(19) United States
(12) Patent Application Publication
(10) Pub. No.: US 2007/0275484 A1
(43) Pub. Date: Nov. 29, 2007

(54) FERROELECTRIC MEMORY AND METHOD FOR MANUFACTURING THE SAME

(75) Inventor: Hiroyuki MITSUI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/749,999

(22) Filed: May 17, 2007

(30) Foreign Application Priority Data
May 24, 2006 (JP) 2006-143927

(51) Int. Cl. H01L 21/00

(52) U.S. Cl. 438/3

(57) ABSTRACT

A method for manufacturing a ferroelectric memory, comprising the steps of: (a) forming a conductive layer; (b) heating a surface of the conductive layer in an atmosphere containing nitrogen; (c) forming an orientation control layer above the conductive layer; (d) forming a first electrode above the orientation control layer; (e) forming a ferroelectric layer above the first electrode; and (f) forming a second electrode above the ferroelectric layer.

The entire disclosure of Japanese Patent Application No. 2006-143927, filed May 24, 2006 is expressly incorporated by reference herein.

### BACKGROUND

1. Technical Field

The present invention relates to ferroelectric memories and methods for manufacturing the same.

2. Related Art

A ferroelectric memory device (FeRAM) is a nonvolatile memory that is capable of low voltage and high speed operations, and its memory cell can be composed of one transistor and one capacitor (1T/1C), such that integration to the level of DRAM is possible. Accordingly, ferroelectric memory devices are highly expected as large capacity nonvolatile memories.

In order to make a ferroelectric capacitor composing a ferroelectric memory device to demonstrate its ferroelectric characteristics to the full, the crystal orientation of each layer composing the ferroelectric capacitor is very important. Japanese laid-open patent application JP-A-2000-277701 describes an example of related art.

### SUMMARY

In accordance with an advantage of some aspects of the invention, it is possible to provide a ferroelectric memory having a ferroelectric layer whose crystal orientation is excellently controlled and a method for manufacturing such a ferroelectric memory.

A method for manufacturing a ferroelectric memory in accordance with an embodiment of the invention includes the steps of: (a) forming a conductive layer; (b) heating a surface of the conductive layer in an atmosphere containing nitrogen; (c) forming an orientation control layer above the conductive layer; (d) forming a first electrode above the orientation control layer; (e) forming a ferroelectric layer above the first electrode; and (f) forming a second electrode above the ferroelectric layer.

In the method for manufacturing a ferroelectric memory in accordance with the present embodiment, the surface of the conductive layer can be planarized in the step (b) by heating the surface in an atmosphere containing nitrogen.

In the method for manufacturing a ferroelectric memory in accordance with the present embodiment, the orientation control layer may include a nitride of titanium.

In the method for manufacturing a ferroelectric memory in accordance with the present embodiment, the step (c) may include the steps of: (c1) forming a titanium layer and (c2) nitriding the titanium layer.

In the method for manufacturing a ferroelectric memory in accordance with the present embodiment, the titanium layer may be nitrided in the step (c2) by heating the titanium layer in a nitrogen atmosphere.

In the method for manufacturing a ferroelectric memory in accordance with the present embodiment, before the step (c1), plasma of ammonia gas may be excited, and the plasma can be irradiated to a surface area where the titanium layer is formed.

In the method for manufacturing a ferroelectric memory in accordance with the present embodiment, the orientation control layer may include a nitride of titanium and aluminum.

In the method for manufacturing a ferroelectric memory in accordance with the present embodiment, the step (c) may include the steps of (c1) forming a titanium aluminum layer, and (c2) nitriding the titanium aluminum layer.

In the method for manufacturing a ferroelectric memory in accordance with the present embodiment, the titanium aluminum layer may be nitrided in the step (c2) by heating the titanium aluminum layer in a nitrogen atmosphere.

In the method for manufacturing a ferroelectric memory in accordance with the present embodiment, before the step (c1), plasma of ammonia gas may be excited, and the plasma may be irradiated to a surface area where the titanium aluminum layer is formed.

The method for manufacturing a ferroelectric memory in accordance with the present embodiment may further include the step of forming a barrier layer above the orientation control layer, between the step (c) and the step (d).

In the method for manufacturing a ferroelectric memory in accordance with the present embodiment, the barrier layer may be composed of a nitride of titanium, or a nitride of titanium and aluminum.

A ferroelectric memory in accordance with an embodiment of the invention includes: a conductive layer containing X as a constituent element; a nitride X layer formed on a top surface of the conductive layer; an orientation control layer formed on a top surface of the nitride X layer; a first electrode formed above the orientation control layer; a ferroelectric layer formed above the first electrode; and a second electrode formed above the ferroelectric layer.

The ferroelectric memory in accordance with the present embodiment may further include a barrier layer formed between the orientation control layer and the first electrode.

In the ferroelectric memory in accordance with the present embodiment, the orientation control layer, the first electrode and the ferroelectric layer may be crystalline, and crystal of the orientation control layer may have an orientation equal to the crystal orientation of the first electrode and the ferroelectric layer.

In the ferroelectric memory in accordance with the present embodiment, crystals of the orientation control layer, the first electrode and the ferroelectric layer may have a (111) orientation.

In the ferroelectric memory in accordance with the present embodiment, the orientation control layer may be composed of a nitride of titanium, or a nitride of titanium and aluminum.

In the ferroelectric memory in accordance with the present embodiment, the orientation control layer, the barrier layer, the first electrode and the ferroelectric layer may be crystalline, and crystal of the orientation control layer and crystal of the barrier layer may have an orientation equal to the crystal orientation of the first electrode and the ferroelectric layer.

In the ferroelectric memory in accordance with the present embodiment, crystals of the orientation control layer, the barrier layer, the first electrode and the ferroelectric layer may have a (111) orientation.

In the ferroelectric memory in accordance with the present embodiment, the orientation control layer may be composed of a nitride of titanium, and the barrier layer may be composed of a nitride of titanium and aluminum.

The ferroelectric memory in accordance with the present embodiment may further include a switching transistor electrically connected to the conductive layer.

The ferroelectric memory in accordance with the present embodiment may further include a dielectric layer formed on the substrate, and a contact hole penetrating the dielectric layer, wherein the conductive layer may be formed at the contact hole.

### BRIEF DESCRIPTION OF THE DRAWINGS

FIG. 1 is a schematic cross-sectional view of a ferroelectric memory in accordance with an embodiment of the invention.

FIG. 2 is a cross-sectional view schematically showing a step of a method for manufacturing the ferroelectric memory shown in FIG. 1.

FIG. 3 is a cross-sectional view schematically showing a step of the method for manufacturing the ferroelectric memory shown in FIG. 1.

FIG. 4 is a cross-sectional view schematically showing a step of the method for manufacturing the ferroelectric memory shown in FIG. 1.

FIG. 5 is a cross-sectional view schematically showing a step of the method for manufacturing the ferroelectric memory shown in FIG. 1.

FIG. 6 is a cross-sectional view schematically showing a step of the method for manufacturing the ferroelectric memory shown in FIG. 1.

FIG. 7 is a cross-sectional view schematically showing a step of the method for manufacturing the ferroelectric memory shown in FIG. 1.

FIG. 8 is a cross-sectional view schematically showing a step of the method for manufacturing the ferroelectric memory shown in FIG. 1.

FIG. 9 is a cross-sectional view schematically showing a step of the method for manufacturing the ferroelectric memory shown in FIG. 1.

FIG. 10 is a cross-sectional view schematically showing a step of the method for manufacturing the ferroelectric memory shown in FIG. 1.

FIG. 11 is a view showing a SEM image of a tungsten layer formed in Experimental Example 1.

FIG. 12 is a view showing a SEM image of a tungsten layer and a tungsten nitride layer formed in Experimental Example 1.

FIG. 13 is a graph showing the intensity of diffraction peaks at the (002) orientation in XRD patterns of titanium layers formed in Experimental Example 2.

### DESCRIPTION OF EXEMPLARY EMBODIMENTS

Preferred embodiments of the invention are described with reference to the accompanying drawings.

### 1. FERROELECTRIC MEMORY

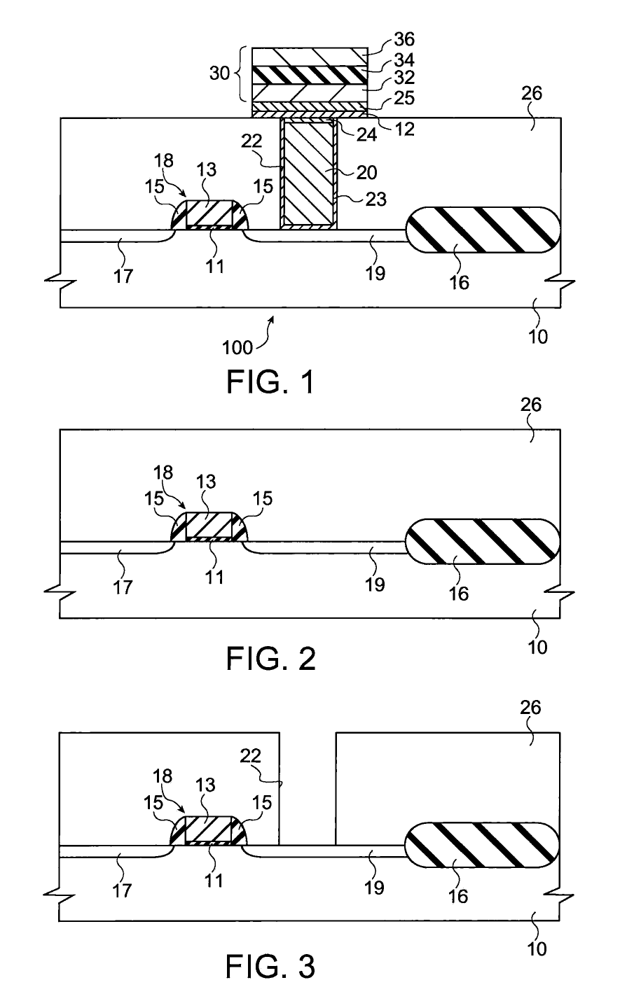

FIG. 1 is a schematic cross-sectional view of a ferroelectric memory 100. As shown in FIG. 1, the ferroelectric memory 100 includes a ferroelectric capacitor 30, an orientation control layer 12, a dielectric layer 26, a plug 20, a first barrier layer 25, and a switching transistor 18 for the ferroelectric capacitor 30. It is noted that, in the present embodiment, a 1T/1C type memory cell is described, but the applicability of the invention is not limited to a 1T/1C memory cell.

The transistor 18 includes a gate dielectric layer 11, a gate conductive layer 13 provided on the gate dielectric layer 11, and a first impurity region 17 and a second impurity region 19 that define source and drain regions. Further, the plug (conductive layer) 20 is electrically connected to the switching transistor 18. The dielectric layer 26 is formed between the ferroelectric capacitor 30 and the transistor 18. The dielectric layer 26 may be composed of any material without any particular limitation, but may be composed of silicon oxide.

The ferroelectric capacitor 30 is provided above the plug 20 that is provided in the dielectric layer 26. The plug 20 is formed above the second impurity region 19. The plug 20 is formed in a manner to embed the contact hole 22 that penetrates the dielectric layer 26. The plug 20 includes an element X as a constituent element. The element X is a high melting point metal, such as, for example, tungsten, molybdenum, tantalum, titanium, nickel or the like, and may preferably be tungsten from the viewpoint of device reliability.

Also, the ferroelectric memory 100 further includes, inside the contact hole 22, a second barrier layer 23 formed on a side surface and a bottom surface of the contact hole 22, and a X nitride layer 24 formed on the plug 20. The plug 20 is covered by the second barrier layer 23 and the X nitride layer 24.

The orientation control layer 12 is formed on the dielectric layer 26 and the X nitride layer 24. The orientation control layer 12 is composed of a nitride of titanium (TiN) or a nitride of titanium and aluminum (TiAlN), and may preferably be composed of TiN that is high in orientation controllability. It is noted that at least a part of the orientation control layer 12 may be crystalline.

The first barrier layer 25 is formed on the orientation control layer 12. The first barrier layer 25 has an oxygen barrier function. The first barrier layer 25 is composed of a nitride of titanium (TiN) or a nitride of titanium and aluminum (TiAlN), and may preferably be composed of TiAlN that is high in oxygen barrier capability. Also, the first barrier layer 25 can improve the adhesion of a first electrode 32. It is noted that at least a part of the first barrier layer 25 may be crystalline.

The ferroelectric capacitor 30 includes a first electrode 32 provided on the first barrier layer 25, a ferroelectric layer 34 provided on the first electrode 32 and a second electrode 36 provided on the ferroelectric layer 34. The first electrode 32 and the ferroelectric layer 34 may be at least in part crystalline. The first electrode 32 may be composed of at least one kind of metal selected from iridium, platinum, ruthenium, rhodium, palladium, osmium and iridium, and may preferably be composed of platinum or iridium, and may more preferably be composed of iridium that is high in device reliability. The first electrode 32 may be in a single layer film or a multilayer film of laminated layers.

The ferroelectric layer 34 includes a ferroelectric material. The ferroelectric material has a perovskite crystal structure and may be expressed by a general formula of A_{1-b}B₁₋ₐXₐO₃. The element A includes Pb. The element B is composed of at least one of Zr and Ti. The element X may be composed of at least one of V, Nb, Ta, Cr, Mo and W. As the ferroelectric material included in the ferroelectric layer 34, a known material that can be used as a ferroelectric film can be used. For example, perovskite type oxides, such as, (Pb(Zr, Ti)O₃) (PZT), SrBi₂Ta₂O₉ (SBT), and (Bi, La)₄Ti₃O₁₂ (BLT), and bismuth layered compounds can be enumerated. Among the materials listed above, PZT is preferable as the material of the ferroelectric layer 34.

When PZT is used as the material of the ferroelectric layer 34, the content of titanium in the PZT may preferably be greater than the content of zirconium in order to obtain a greater amount of spontaneous polarization. The PZT with such a composition belongs to tetragonal crystal, and its spontaneous polarization axis is the c-axis. Accordingly, in principle, the maximum amount of polarization can be obtained by orienting in the c-axis. However, it is in effect very difficult to obtain a c-axis single oriented film, and an a-axis orientation component that is orthogonal to the c-axis may concurrently exist. Because the a-axis orientation component does not contribute to polarization reversal, there is a possibility that the device ferroelectric characteristics may be damaged. This problem is solved by making the crystal orientation of PZT used in the ferroelectric layer 34 in a (111) orientation. When the crystal orientation of PZT is in a (111) orientation, the polarization axis tilts such that a loss in the induced charge occurs accordingly, but instead, all of the crystal components can contribute to polarization reversal. Therefore, the charge can rather be effectively retrieved, compared to the state in which c-axis orientation and a-axis orientation components coexist. Accordingly, when the ferroelectric layer 34 is composed of PZT, and the content of titanium in the PZT is greater than the content of zirconium therein, the crystal orientation of the PZT may preferably be in a (111) orientation, because the hysteresis characteristic of the PZT is excellent in this orientation.

The second electrode 36 may be composed of any of the materials described above as an example of the material that can be used as the first electrode 32, or may be composed of aluminum, silver, nickel or the like. Also, the second electrode 36 may be in a single layer film, or a multilayer film of laminated layers. The second electrode 36 may preferably be composed of platinum or a laminated film of layers of iridium oxide and iridium.

The second barrier layer 23 is formed on a bottom surface and a side surface of the contact hole 22. The second barrier layer 23 may be composed of a conductive material, and may be composed of, for example, at least one layer of either a nitride of titanium (TiN) or a nitride of titanium and aluminum (TiAlN). The second barrier layer 23 can improve adhesion of the plug 20, prevent diffusion and oxidation of the plug 20, and lower the resistance of the plug 20.

The X nitride layer 24 is formed on the plug 20. The X nitride layer 24 includes X nitride that is formed by nitriding the element X which is a conductive material. As the element X, the aforementioned high melting point metal, such as, tungsten, molybdenum, tantalum, titanium, nickel and the like can be used. In this manner, by forming the X nitride layer 24 on the plug 20, the orientation control layer 12a on the plug 20 can be provided with excellent crystal orientation. This is because the top surface of the X nitride layer 24 has less unevenness and is smoother, compared to the top surface of the plug 20, such that the orientation control layer 12 formed thereon can be more readily oriented in a desired orientation. As a result, the orientation control layer 12 with excellent crystal orientation can be formed, and the orientation control function to be described below of the orientation control layer 12 can be improved.

The orientation control function of the orientation control layer 12 is described next. The orientation control layer 12 is crystalline, and has a desired crystal orientation. Accordingly, because the first barrier layer 25 is formed on the orientation control layer 12, the first barrier layer 25, when its material is crystalline, is influenced by the crystal orientation of the orientation control layer 12, and can have an orientation equal to that of the orientation control layer 12. According to the present embodiment, the orientation control layer 12 and the first barrier layer 25 are both composed of a nitride of titanium or a nitride of titanium and aluminum, and therefore can have a (111) orientation. In other words, when the orientation control layer 12 has a (111) orientation with an excellent crystalline structure, the first barrier layer 25 can also have a (111) orientation with an excellent crystalline structure.

Because the first electrode 32 is formed on the barrier layer 25, the first electrode 32, when its material is crystalline, is influenced by the crystal orientation of the first barrier layer 25, and can have an orientation equal to that of the first barrier layer 25. In other words, because the first electrode 32 is formed above the orientation control layer 12, the first electrode 32 is influenced by the crystal orientation of the orientation control layer 12, and can have an orientation equal to that of the orientation control layer 12. According to the present embodiment, the orientation control layer 12 and the first barrier layer 25 are both composed of a nitride of titanium or a nitride of titanium and aluminum, and therefore can have a (111) orientation. Accordingly, the crystal orientation of the first electrode 32 can be readily oriented in a (111) orientation. In other words, when the orientation control layer 12 and the first barrier layer 25 have a (111) orientation with an excellent crystalline structure, the first electrode 32 can also have a (111) orientation with an excellent crystalline structure.

Because the ferroelectric layer 34 is formed on the first electrode 32, the ferroelectric layer 34, when its material is crystalline, is influenced by the crystal orientation of the first electrode 32, and can have an orientation equal to that of the first electrode 34. In other words, because the ferroelectric layer 34 is formed above the orientation control layer 12 and the first barrier layer 25, the ferroelectric layer 34 is influenced by the crystal orientation of the orientation control layer 12 and the first barrier layer 25, and can have an orientation equal to that of the orientation control layer 12 and the first barrier layer 25. According to the present embodiment, the orientation control layer 12 and the first barrier layer 25 are both composed of a nitride of titanium or a nitride of titanium and aluminum, and therefore can have a (111) orientation. Also, similarly, the first electrode 32 can have a (111) orientation when it is composed of the aforementioned material, such as, for example, platinum, iridium or the like. Accordingly, the crystal orientation of the ferroelectric layer 34 can be readily oriented in a (111) orientation. In other words, when the orientation control layer 12, the first barrier layer 25 and the first electrode 32 have a (111) orientation with an excellent crystalline structure, the ferroelectric layer 34 can also have a (111) orientation with an excellent crystalline structure.

The ferroelectric layer 34 may be composed of a perovskite type oxide, a bismuth layered compound or the like, as described above, and its crystal orientation may preferably be in a (111) orientation. The ferroelectric layer 34 in accordance with the present embodiment, as being formed above the X nitride layer 24, the orientation control layer 12, the first barrier layer 25 and the first electrode 32, can readily have a (111) orientation. Therefore, the ferroelectric memory 100 can be obtained with excellent hysteresis characteristics.

### 2. MeETHOD FOR MANUFACTURING FERROELECTRIC MEMORY

Next, an example of a method for manufacturing a ferroelectric memory 100 shown in FIG. 1 is described with reference to the accompanying drawings. FIGS. 2-10 are cross-sectional views schematically showing the steps of a process for manufacturing the ferroelectric memory device 100 shown in FIG. 1.

First, as shown in FIG. 2, a transistor 18 and a device isolation region 16 are formed. More concretely, the transistor 18 and the device isolation region 16 are formed on a semiconductor substrate 10, and a dielectric layer 26 is deposited thereon. The transistor 18, the device isolation region 16, and the dielectric layer 26 can be formed by a known method.

Next, as shown in FIG. 3, a contact hole 22 is provided in a manner to penetrate the dielectric layer 26. The contact hole 22 may be formed over, for example, a second impurity region 19. The contact hole 22 may be formed by using a photolithography technique. More concretely, a resist layer (not shown) that opens in a part of the dielectric layer 26 is formed, and the dielectric layer 26 is etched at the open area of the resist layer, whereby the contact hole 22 can be formed.

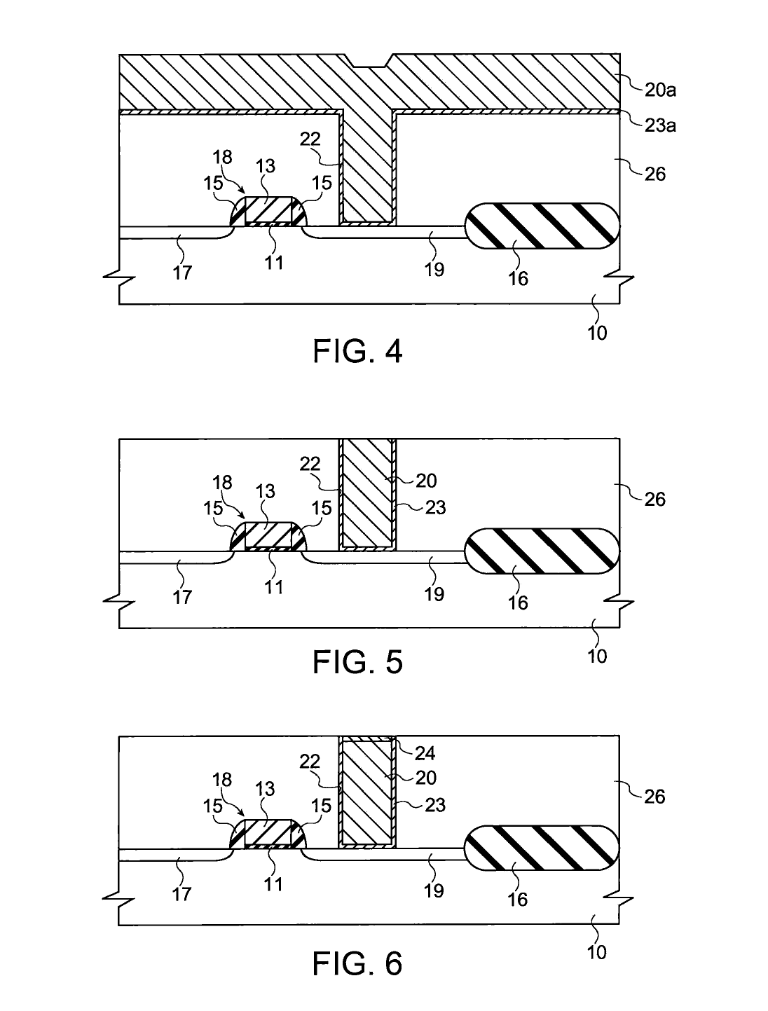

Next, as shown in FIG. 4, a second barrier layer 23a is continuously formed on a side surface and a bottom surface of the contact hole 22 and on the dielectric layer 26. The second barrier layer 23a may be composed of a nitride of titanium (for example, TiN) or a nitride of titanium and aluminum (for example, TiAlN), and may be formed by a known method, such as, a reactive sputtering.

Next, as shown in FIG. 4, a conductive material X is embedded in the contact hole 22, thereby forming a conductive layer 20a. The conductive layer 20a can be embedded by using, for example, a CVD method or a sputter method.

Next, as shown in FIG. 5, the conductive layer 20a and the second barrier layer 23a are polished, whereby a plug 20 and a second barrier layer 23 are formed. In the polishing step, a chemical mechanical polishing (CMP) method can be used. By the polishing step, the dielectric layer 26 can be exposed.

Then, as shown in FIG. 6, a surface of the plug 20 is nitrided to form an X nitride layer 24. As the method for nitriding the surface of the plug 20, any appropriate method can be selected according to its material. For example, a method in which the surface of the plug 20 is annealed in an atmosphere containing nitrogen, thereby nitriding the surface of the plug 20, may be used. The atmosphere containing nitrogen may be an atmosphere containing ammonium or its plasma. The annealing temperature may preferably be 600-800° C., and more preferably be 600-725° C. By this, the X nitride layer 24 can be obtained. The X nitride layer 24 may need to be formed only in a surface layer of the plug 20, and its film thickness may be, for example, about several ten nm. Also, the X nitride layer 24 may not need to have a crystalline structure, and can be in an amorphous state.

By forming the X nitride layer 24 in this manner, an orientation control layer 12a to be described below can have an excellent crystal orientation on the plug 20. More concretely, by forming the X nitride layer 24, a surface region where the orientation control layer 12a is formed is planarized, and is terminated with —NH, such that atoms composing a metal layer 14a to be formed can readily be migrated. As a result, it is assumed that the constituent atoms of the metal layer 14a are promoted to be regularly arranged due to their self-alignment property, whereby the metal layer 14a with an excellent crystal orientation can be formed.

Next, an orientation control layer 12a (see FIG. 8) is formed. First, plasma of ammonium gas is excited, and the plasma is irradiated to a surface area where the orientation control layer 12a is to be formed (hereafter referred to an “ammonium plasma treatment”). By the ammonium plasma treatment, the surface of the area where the orientation control layer 12a is to be formed is terminated with —NH, such that, in a step of forming a metal layer 14a to be described below, the constituent atoms of the metal layer 14a can be readily migrated. As a result, it is assumed that the constituent atoms of the metal layer 14a are promoted to be regularly arranged (in a closed-packed state in this case) due to their self-alignment property, whereby the metal layer 14a with an excellent crystal orientation can be formed. Also, by conducting an ammonium plasma treatment before a polishing treatment to be described below, the effectiveness of the aforementioned ammonia plasma treatment can be enhanced. Also, —NH would likely be maintained at the surface of the X nitride layer 24 such that, by further treating the surface of the X nitride layer 24 with an ammonium plasma treatment, the effectiveness of the ammonium plasma treatment can be maintained for a long time.

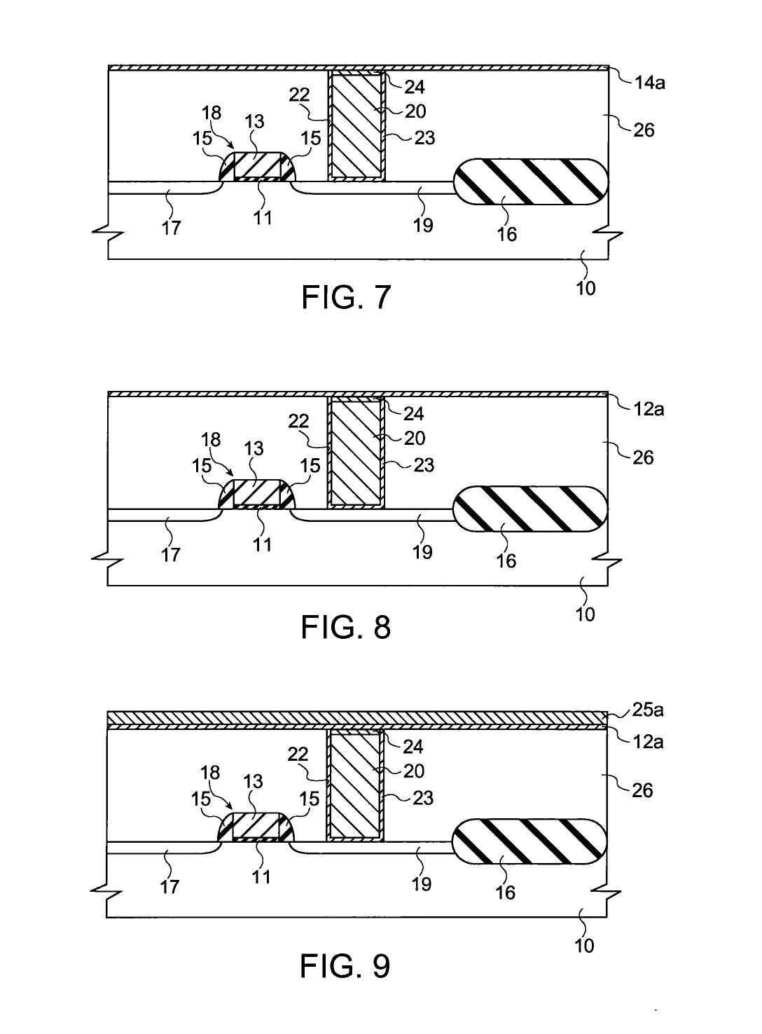

Then, as shown in FIG. 7, a metal layer 14a composed of a titanium layer or a titanium aluminum layer is formed. As the film forming method for forming the metal layer 14a, any method may be appropriately selected according to its material, and for example, a sputter method and a CVD method can be enumerated. Also, as the substrate temperature at the time of forming the metal layer 14a, any substrate temperature can be appropriately selected according to its material. For example, the metal layer 14a can be formed by a sputter method in an inert gas atmosphere (for example, argon gas). In this case, the substrate temperature at the time of forming the metal layer 14a may preferably be between room temperature and 400° C., may more preferably between 100° C. and 400° C., and even more preferably between 100° C. and 300° C., such that the orientation control layer 12 has a (111) orientation.

The orientation control layer 12a having a (111) orientation is obtained because of the following reason. Ti or TiAl composing the metal layer 14a has a strong self-orientation property. The metal layer 14a has crystals with a (001) orientation due to its self-orientation property. For this reason, it is assumed that, by a nitriding step to be described below, nitrogen atoms enter gaps in the crystals of Ti or TiAl of the metal layer 14a in the state in which they are oriented in a (001) orientation, such that the orientation control layer 12a having a (111) orientation can be obtained. It is noted that the greater the content of titanium in a titanium layer or a titanium aluminum layer, the greater its self-orientation property. Therefore, by using a titanium layer, an orientation control layer 12 having an excellent orientation can be obtained, and the orientation of the ferroelectric layer 34 can consequently be made favorable. Also, as described above, by forming the metal layer 14a composed of a titanium layer or a titanium aluminum layer after an ammonium plasma treatment has been conducted, the metal layer 14a with an excellent orientation can be obtained.

Then, as shown in FIG. 8, the metal layer 14a is nitrided, thereby forming a crystalline orientation control layer 12a composed of nitride. As the method for nitriding the metal layer 14a, any method can be appropriately selected according to its material. For example, a method in which the metal layer 14a is annealed in an atmosphere containing nitrogen to thereby nitride the metal layer 14a can be enumerated. As the atmosphere containing nitrogen, an atmosphere containing ammonium or its plasma may be used. It is noted that the annealing may preferably be conducted below the melting point of the metal layer 14a. By conducting the annealing in such a temperature range, nitrogen atoms can be introduced in gaps in the crystal lattice of the crystalline structure composing the metal layer 14a in the state in which the crystal orientation of the metal layer 14a is maintained. The annealing may preferably be conducted at 350° C. to 650° C., and more preferably be conducted at 500° C. to 650° C. As a result, the orientation control layer 12a can be obtained.

When the metal layer 14a contains titanium and aluminum, the orientation control layer 12a can be composed of a nitride of titanium and aluminum (for example, TiAlN); and when the metal layer 14a contains titanium (Ti), the orientation control layer 12a can be composed of a nitride of titanium (for example, TiN). Ti and TiAl belongs to hexagonal crystal and has a (001) orientation. The metal layer 14a may be 20 nm in thickness. Also, the orientation control layer 12a that is obtained by nitriding the metal layer 14a is composed of TiN or TiAlN in face-centered-cubic crystal, and the TiN and TiAl have a (111) orientation because they are influenced by the orientations of their respective raw materials, Ti and TiAl (of the metal layer 14a).

Next, as shown in FIG. 9, a first barrier layer 25a is formed on the top surface of the plug 20 and the orientation control layer 12a. The first barrier layer 25a may be composed of a nitride of titanium (for example, TiN) or a nitride of titanium and aluminum (for example, TiAlN), and may be formed by a known method such as a reactive sputtering method. By forming the first barrier layer 25a on the orientation control layer 12a, the crystal orientation of the orientation control layer 12a can be reflected in the first barrier layer 25a, and the crystallinity of the first barrier layer 25 can be considerably improved.

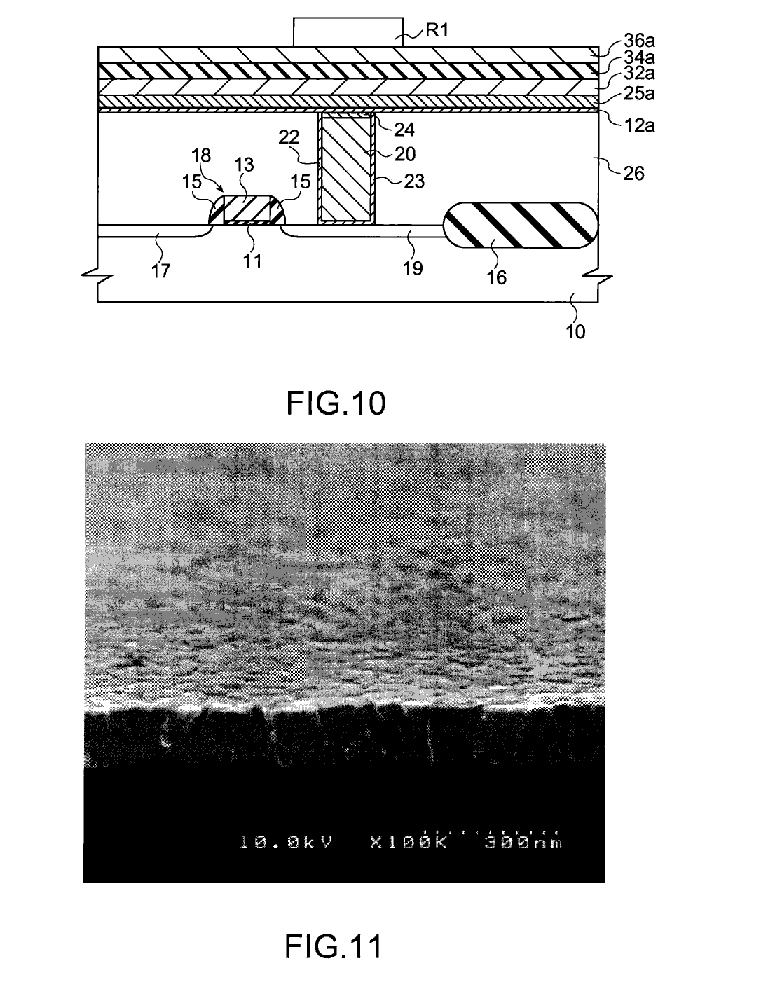

Next, as shown in FIG. 10, a first electrode 32a is formed on the first barrier layer 25a. By forming the crystalline first barrier layer 25a on the first electrode 32a, the crystal orientation of the orientation control layer 12a and the first barrier layer 25a can be reflected in the first electrode 32a, such that the crystallinity of the first electrode 32a can be considerably improved. In accordance with the present embodiment, because the crystal orientation of the orientation control layer 12a is in a (111) orientation, the first barrier layer 25a and at least a portion of the first electrode 32a can be formed to be crystalline having a (111) orientation.

As the film forming method for forming the first electrode 32a, any method may be appropriately selected according to its material, and for example, a sputter method, a vacuum vapor deposition method, or a CVD method can be used.

Next, as shown in FIG. 10, a ferroelectric layer 34a is formed on the first electrode 32a. By forming the ferroelectric layer 34a on the first electrode 32a, the crystal orientation of the first electrode 32a can be reflected in the ferroelectric layer 34a. In accordance with the present embodiment, because at least a portion of the first electrode 32a is crystalline with a (111) orientation, the ferroelectric layer 34a can be formed in a (111) orientation.

As the film forming method for forming the ferroelectric layer 34a, any method may be appropriately selected according to its material. For example, a solution coating method (including, for example, a sol-gel method and a MOD (metal organic decomposition) method), a sputter method, a CVD method, and a MOCVD (metal organic chemical vapor deposition) method can be used.

Then, as shown in FIG. 10, a second electrode 36a is formed on the ferroelectric layer 34a. As the film forming method for forming the second electrode 36a, any method may be appropriately selected according to its material. For example, a sputter method and a CVD method can be enumerated. Then, a resist layer R1 having a predetermined pattern is formed on the second electrode 36a. By using the resist layer R1 as a mask, a patterning step is conducted by a photolithography method. By this, a stacked type ferroelectric capacitor 30 having a first electrode 32 provided on the first barrier layer 25, a ferroelectric layer 34 provided on the first electrode 32 and a second electrode 36 provided on the ferroelectric layer 34 can be obtained (see FIG. 1).

By the method for forming the ferroelectric memory 100 in accordance with the present embodiment, the X nitride layer 24 is formed on the plug 20, such that the metal layer 14a with an excellent crystal orientation can be formed, and the orientation control layer 12a with an excellent crystal orientation can consequentially be obtained.

By the method for forming the ferroelectric memory 100 in accordance with the present embodiment, the crystalline metal layer 14a is nitrided, thereby forming the crystalline orientation control layer 12a composed of a nitride, such that the first barrier layer 25a, the first electrode 32a and the ferroelectric layer 34a in which the crystalline structure of the orientation control layer 12a is reflected can be formed. In other words, by forming the orientation control layer 12a having a predetermined crystal orientation, the ferroelectric layer 34a having a desired crystal orientation can be formed. By this, the ferroelectric memory 100 that excels in hysteresis characteristics can be obtained.

### 3. EXPERIMENTAL EXAMPLE

Next, the ferroelectric memory 100 in accordance with the present embodiment is more concretely described by using experimental examples.

### 3.1. Experimental Example 1

In Experimental Example 1, how the presence of an X nitride layer 24 influences the smoothness of the surface was investigated.

First, a conductive layer 20a composed of tungsten (a tungsten layer) was formed on a silicon substrate by a CVD method. A SEM image of the tungsten layer obtained is shown in FIG. 11.

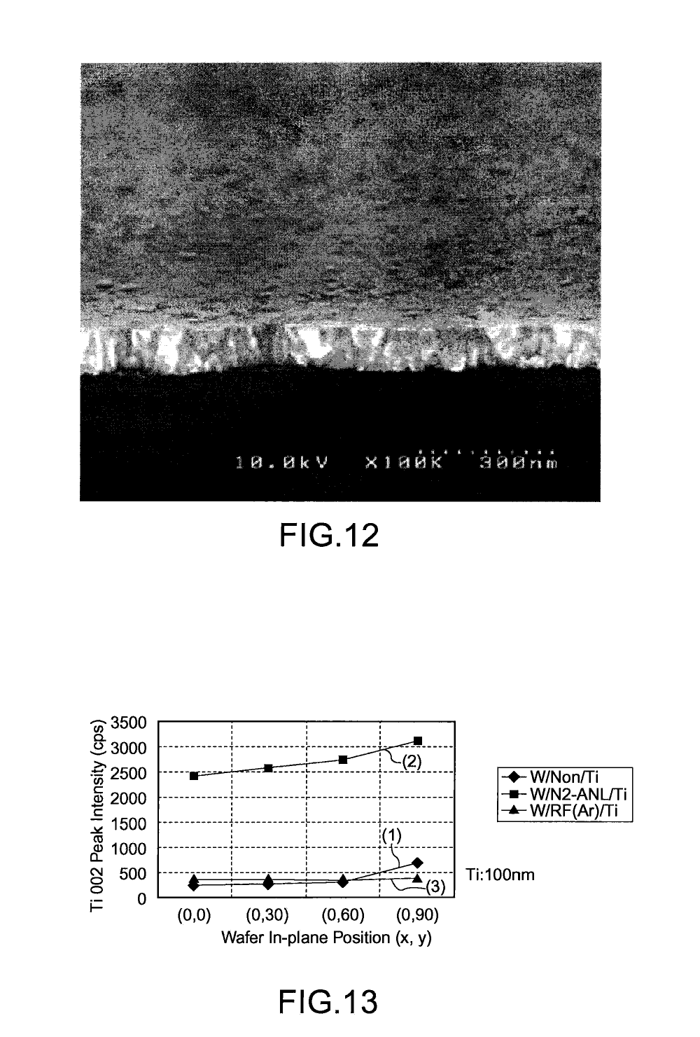

Then, the tungsten layer was treated with a heat treatment (RTA) in a nitrogen atmosphere for nitriding the layer, whereby an X nitride layer 24 composed of tungsten nitride was formed. The temperature in the heat treatment was 650° C., and the treatment time was 2 minutes. An SEM image of the tungsten layer and the tungsten nitride layer obtained is shown in FIG. 12.

It is confirmed from FIG. 11 and FIG. 12 that the surface of the tungsten nitride layer has less irregularity and excels in smoothness, compared to the surface of the tungsten layer.

### 3.2. Experimental Example 2

In Experimental Example 2, how the smoothness in the forming region of the orientation control layer 12 influences the crystal orientation of the orientation control layer 12 was investigated. Titanium layers were obtained by the following methods (1)-(3), and 002 peak intensities derived from the crystalline titanium were investigated according to XRD patterns of the titanium layers obtained.

(1) A conductive layer 20a composed of tungsten (a tungsten layer) was formed on a silicon substrate by a CVD method, and then a metal layer 14a composed of a titanium layer was formed. The titanium layer was formed by sputtering. The titanium layer was formed in a film forming condition with the flow quantity of atmosphere (argon) being 50 [sccm], the film forming power being 1.5 [kW], and the substrate temperature being 150[° C.].

(2) A conductive layer 20a composed of tungsten (a tungsten layer) was formed on a silicon substrate by a CVD method, and then the layer was nitrided by a heat treatment (RTA) in a nitrogen atmosphere whereby an X nitride layer 24 composed of tungsten nitride was formed. The temperature in the heat treatment was 650° C., and the heat treatment time was 2 minutes. Then a metal layer 14a composed of a titanium layer was formed. The titanium layer was formed by sputtering. The titanium layer was formed in a film forming condition with the flow quantity of atmosphere (argon) being 50 [sccm], the film forming power being 1.5 [kW], and the substrate temperature being 150[° C.].

(3) A conductive layer 20a composed of tungsten (a tungsten layer) was formed on a silicon substrate by a CVD method, and the top surface of the tungsten layer was roughened by RF sputtering. Then, a metal layer 14a composed of a titanium layer was formed. The titanium layer was formed by sputtering. The titanium layer was formed in a film forming condition with the flow quantity of atmosphere (argon) being 50 [sccm], the film forming power being 1.5 [kW], and the substrate temperature being 150[° C.].

According to FIG. 13, the titanium layer having the tungsten nitride layer formed at its base has a 002 peak intensity derived from the crystalline titanium having a (001) orientation which is more than five times that of the titanium layer without a tungsten nitride layer formed at its base. Accordingly, the titanium layer formed on the X nitride layer 24 excels in crystal orientation, and therefore the ferroelectric layer 34 of the ferroelectric memory 100 is also assumed to excel in crystal orientation, and also assumed to excel in hysteresis characteristics.

Embodiments of the invention are described above in detail. However, a person having an ordinary skill in the art should readily understand that many modifications can be made without departing in substance from the novel matter and effect of the invention. Accordingly, those modified examples are also deemed included in the scope of the invention.

Also, the composition and the method for manufacturing a ferroelectric capacitor, an orientation control layer and the like included in a ferroelectric memory in accordance with embodiments of the invention are applicable to other devices, such as, for example, a capacitor included in a piezoelectric device.

What is claimed is:

1. A method for manufacturing a ferroelectric memory, comprising the steps of:
(a) forming a conductive layer;
(b) heating a surface of the conductive layer in an atmosphere containing nitrogen;
(c) forming an orientation control layer above the conductive layer;
(d) forming a first electrode above the orientation control layer;
(e) forming a ferroelectric layer above the first electrode; and
(f) forming a second electrode above the ferroelectric layer.

2. A method for manufacturing a ferroelectric memory according to claim 1, wherein the surface of the conductive layer is planarized in the step (b) by heating the surface in an atmosphere containing nitrogen.

3. A method for manufacturing a ferroelectric memory according to claim 1, wherein the orientation control layer includes a nitride of titanium.

4. A method for manufacturing a ferroelectric memory according to claim 3, wherein the step (c) includes the steps of (c1) forming a titanium layer, and (c2) nitriding the titanium layer.

5. A method for manufacturing a ferroelectric memory according to claim 4, wherein the titanium layer is nitrided in the step (c2) by heating the titanium layer in a nitrogen atmosphere.

6. A method for manufacturing a ferroelectric memory according to claim 4, further comprising, before the step (c1), the steps of exciting plasma of ammonia gas, and irradiating the plasma to a surface area where the titanium layer is formed.

7. A method for manufacturing a ferroelectric memory according to claim 1, wherein the orientation control layer includes a nitride of titanium and aluminum.

8. A method for manufacturing a ferroelectric memory according to claim 7, wherein the step (c) includes the steps of (c1) forming a titanium aluminum layer, and (c2) nitriding the titanium aluminum layer.

9. A method for manufacturing a ferroelectric memory according to claim 8, wherein the titanium aluminum layer is nitrided in the step (c2) by heating the titanium aluminum layer in a nitrogen atmosphere.

10. A method for manufacturing a ferroelectric memory according to claim 8, further comprising, before the step (c1), the steps of exciting plasma of ammonia gas, and irradiating the plasma to a surface area where the titanium aluminum layer is formed.

11. A method for manufacturing a ferroelectric memory according to claim 1, comprising the step of forming a barrier layer above the orientation control layer, between the step (c) and the step (d).

12. A method for manufacturing a ferroelectric memory according to claim 11, wherein the barrier layer is composed one of a nitride of titanium and a nitride of titanium and aluminum.

13. A ferroelectric memory comprising:
a conductive layer containing X as a constituent element;
a nitride X layer formed on a top surface of the conductive layer;
an orientation control layer formed on a top surface of the nitride X layer;
a first electrode formed above the orientation control layer;
a ferroelectric layer formed above the first electrode; and
a second electrode formed above the ferroelectric layer.

14. A ferroelectric memory according to claim 13, further comprising a barrier layer formed between the orientation control layer and the first electrode.

15. A ferroelectric memory according to claim 13, wherein the orientation control layer, the first electrode and the ferroelectric layer are crystalline, and crystal of the orientation control layer has an orientation equal to a crystal orientation of the first electrode and the ferroelectric layer.

16. A ferroelectric memory according to claim 15, wherein crystals of the orientation control layer, the first electrode and the ferroelectric layer have a (111) orientation.

17. A ferroelectric memory according to claim 16, wherein the orientation control layer is composed of one of a nitride of titanium and a nitride of titanium and aluminum.

18. A ferroelectric memory according to claim 14, wherein the orientation control layer, the barrier layer, the first electrode and the ferroelectric layer are crystalline, and crystal of the orientation control layer and crystal of the barrier layer have an orientation equal to a crystal orientation of the first electrode and the ferroelectric layer.

19. A ferroelectric memory according to claim 19, wherein crystals of the orientation control layer, the barrier layer, the first electrode and the ferroelectric layer have a (111) orientation.

20. A ferroelectric memory according to claim 19, wherein the orientation control layer is composed of a nitride of titanium, and the barrier layer is composed of a nitride of titanium and aluminum.

21. A ferroelectric memory according to claim 13, further comprising a switching transistor electrically connected to the conductive layer.

22. A ferroelectric memory according to claim 13, further comprising a dielectric layer formed on the substrate, and a contact hole penetrating the dielectric layer, wherein the conductive layer is formed at the contact hole.
